(19) United States
(12) Patent Application Publication
(10) Pub. No.: US 2024/0421762 A1
(43) Pub. Date: Dec. 19, 2024

(54) POWER DEVICE AND PHOTOVOLTAIC POWER GENERATION DEVICE

(71) Applicant: SUNGROW POWER SUPPLY CO., LTD., Hefei, Anhui (CN)

(72) Inventors: Yonghong LI, Hefei, Anhui (CN); Yongfu WU, Hefei, Anhui (CN); Wenhao LI, Hefei, Anhui (CN); An’an XU, Hefei, Anhui (CN); Jie WU, Hefei, Anhui (CN); Weifeng ZHANG, Hefei, Anhui (CN); Lei SHI, Hefei, Anhui (CN)

(21) Appl. No.: 18/704,225

(22) PCT Filed: May 26, 2022
(86) PCT No.: PCT/CN2022/095225

§ 371 Date: Apr. 24, 2024

(30) Foreign Application Priority Data
Dec. 14, 2021 (CN) 202123155893.1

(51) Int. Cl. H02S 40/32; H02S 40/42; H05K 7/14; H05K 7/20

(52) U.S. Cl. CPC H02S 40/32; H02S 40/425; H05K 7/1427; H05K 7/20909

(57) ABSTRACT

Disclosed are a power device and a photovoltaic power generation device. The power device comprises a case, a first power board, and a second power board, the first power board is arranged in the case, and a first boosting module and an inverter module are arranged on the first power board; the second power board is arranged in the case, the second power board is electrically connected to the first power board, and a second boosting module is arranged on the second power board. According to the technical solution of the present invention, the rated power generation power of the photovoltaic power generation device can be increased, and the flexibility for clients is improved.

This application claims the priority to Chinese Patent Application No. 202123155893.1, titled “POWER DEVICE AND PHOTOVOLTAIC POWER GENERATION DEVICE”, filed on Dec. 14, 2021 with the China National Intellectual Property Administration, which is incorporated herein by reference in its entirety.

### FIELD

The present disclosure relates to the technical field of power generation devices, and in particular to a power device and a photovoltaic power generation device.

### BACKGROUND

Currently, photovoltaic power generation devices using solar energy are widely used due to advantages of energy conservation and high resource utilization. The rated power generated by the conventional photovoltaic power generation device is relatively constant, causing a limited flexibility towards user ends, which cannot meet diverse demands of power stations.

### SUMMARY

A power device and a photovoltaic power generation device are provided according to the present disclosure, to increase rated power generated by the photovoltaic power generation device and improve the flexibility towards user ends.

To this end, a power device is provided according to the present disclosure. The power device includes:
a housing;
a first power board, which is arranged inside the housing, where a first boost module and an inversion module are arranged on the first power board; and
a second power board, which is arranged inside the housing, where the second power board is electrically connected to the first power board, and a second boost module is arranged on the second power board.

In an embodiment, the power device further includes a conductive member, where the conductive member is connected between the first power board and the second power board for the electric connection therebetween.

In an embodiment, at least two inversion modules are arranged on the first power board, a distance from each of the at least two inversion modules to the second boost module is different from each other, and the second boost module is electrically connected to the inversion module, with a minimum distance to the second boost module.

In an embodiment, a first component and a second component are arranged on a surface of the first power board and are spaced apart from each other, and a first heat-dissipation air channel is formed between the first component and the second component: a third component and a fourth component are arranged on a surface of the second power board and are spaced apart from each other, and a second heat-dissipation air channel is formed between the third component and the fourth component; and the first heat-dissipation air channel is in communication with the second heat-dissipation air channel.

In an embodiment, the first heat-dissipation air channel and the second heat-dissipation air channel are located on a same straight line.

In an embodiment, the power device further includes a first heat radiator arranged inside the housing, and the first heat radiator is in contact with the first power board; and/or the power device further includes a second heat radiator arranged inside the housing, and the second heat radiator is in contact with the second power board.

In an embodiment, the power device further includes a heat-dissipation fan arranged on the housing.

In an embodiment, the power device further includes a direct-current input board, where the direct-current input board is arranged inside the housing and is electrically connected to the first power board and the second power board.

In an embodiment, the power device further includes a direct-current input switch, where the direct-current input switch is arranged on the housing, and the direct-current input board is electrically connected to the first power board and the second power board through the direct-current input switch.

In an embodiment, the power device further includes an alternating-current output board, where the alternating-current output board is arranged inside the housing and is electrically connected to the first power board.

In order to achieve the above objective, a photovoltaic power generation device is provided according to the present disclosure. The photovoltaic power generation device includes a photovoltaic assembly and the power device described above. The photovoltaic assembly is electrically connected to the first power board and the second power board.

According to the technical solutions of the present disclosure, by arranging the second boost module different from the first boost module in type and specification on the second boost module, the function of the first power board can be expanded, and the rated power generated by the power device can be increased. In this way, the power device can be applicable to different direct-current inputs, thereby applying to different application situations of the user ends, which significantly improves the flexibility of the power device. As distinguished from the conventional development process, where a whole power device is customized and developed according to different user ends, the power device in the present disclosure can save costs for design and development and improve development efficiency. In addition, the second power board is arranged on the basis of the first power board, which facilitates the fabrication and installment of the power boards. By providing separable power boards, which is applicable to the fabrication and processing of the conventional circuit board, it can eliminate the limitation on the improvement in the power of the power device due to the limitation of the processing capacity.

### BRIEF DESCRIPTION OF THE DRAWINGS

For clearer illustration of the technical solutions according to embodiments of the present disclosure or conventional techniques, hereinafter are briefly described the drawings to be applied in embodiments of the present disclosure or conventional techniques. Apparently, the drawings in the following descriptions are only some embodiments of the present disclosure, and those skilled in the art can obtain other drawings from these drawings without any creative effort.

FIG. 1 is a schematic structural diagram of a power device according to an embodiment of the present disclosure; and

FIG. 2 is a schematic structural diagram of the power device shown in FIG. 1 from another perspective.

### REFERENCE SIGNS IN THE DRAWINGS

| Reference | | Reference | |
|---|---|---|---|
| sign | Name | sign | Name |
| 100 | power device | 30 | second power board |
| 10 | housing | 31 | second boost module |
| 20 | first power board | 32 | third component |
| 21 | first boost module | 33 | fourth component |
| 22 | inversion module | 34 | second air channel |
| 23 | first component | 40 | conductive member |
| 24 | second component | 50 | direct-current input |
| 25 | first air channel | | switch |

The implementations, functional features and advantages of the present disclosure are further described in conjunction with embodiments by referring to the drawings.

### DETAILED DESCRIPTION

Hereinafter, technical solutions in embodiments of the present disclosure are described clearly and thoroughly with reference to the drawings and the embodiments of the present disclosure. Apparently, the embodiments described are only part embodiments of the present disclosure, rather than all embodiments. All other embodiments obtained by those skilled in the art without any creative efforts based on the embodiments of the present disclosure fall within the protection scope of the present disclosure.

It should be noted that, all directional indicators (such as up, down, left, right, front, back, etc.) in the embodiments of the present disclosure are only used for explaining a relative position relationship and movement situation and the like among components in a specific orientation (as shown in the figures). If the specific orientation changes, the directional indicators change accordingly.

In addition, if there are descriptions related to “first” and “second” in the embodiments of the present disclosure, the descriptions of “first” and “second” are only used for descriptive purposes, and may not be understood as indicating or implying its relative importance or implicitly indicating the number of the indicated technical features. Therefore, features defined with “first” or “second” may include at least one of the features explicitly or implicitly. In addition, the technical solutions between the various embodiments can be combined with each other on the premise that such combination can be implemented by those skilled in the art. If a combination of technical solutions is contradictory or impossible to be implemented, such combination does not exist and is not within the protection scope of the present disclosure.

A power device 100 is provided according to the present disclosure.

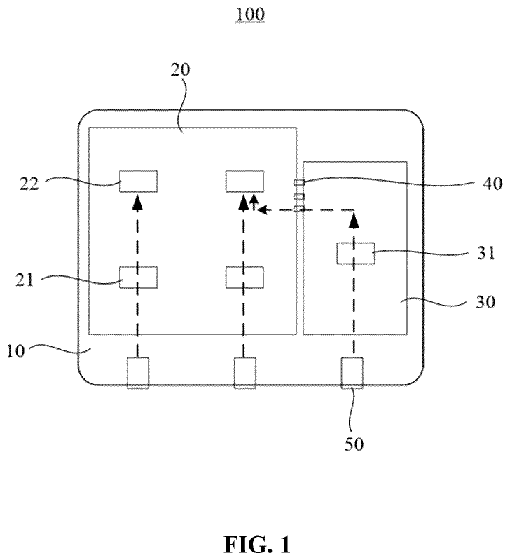

In an embodiment of the present disclosure, as shown in FIG. 1, the power device 100 includes a housing 10, a first power board 20, and a second power board 30. The first power board 20 is arranged inside the housing 10. A first boost module 21 and an inversion module 22 are arranged on the first power board 20. The second power board 30 is arranged inside the housing 10. The second power board 30 is electrically connected to the first power board 20. A second boost module 31 is arranged on the second power board 30.

In an embodiment, in addition to the first boost module 21 and the inversion module 22, the first power board 20 may further be provided with other conventional power components such as a high-power resistor, or a high-capacity capacitor, etc. Similarly, in addition to the second boost module 31, the second power board 30 may further be provided with other conventional power components. The first power board 20 is different from the second power board 30 in that the first power board 20 is configured to boost and invert the direct-current power, and the second power board 30 is configured to boost the direct-current power.

In the embodiment, the power device 100 may boost and invert the direct-current power converted from clean energy (i.e., solar energy or wind energy) into the alternating-current power, and output the alternating-current power. Where, the direct-current power may be generated through solar energy power generation or wind power generation, which is inputted by a direct-current input board to the first power board 20 and the second power board 30. The second power board 30 boosts the direct-current power inputted by the direct-current input board, and transmits the direct-current power to the second power board 30. The first power board 20 boosts and inverts the direct-current power inputted by the direct-current input board and the second power board 30, to convert the direct-current power into required alternating-current power. The alternating-current power is outputted by an alternating-current output board to a power grid.

In the embodiment, the first power board 20 is a primary power board, and the second power board 30 is a secondary power board. The first power board 20 outputs constant power, while the second power board 30 outputs variable power. In an embodiment, the second boost module 31 is different from the first boost module 21 in type and specification. In other words, the power of the first power board 20 is determined according to conventional power required by universal user ends, and the power of the second power board 30 is adaptively determined according to different power requirements of some user ends, so that the second power board 30 is used to complement the first power board 20.

By arranging the second boost module 31 different from the first boost module 21 in type and specification on the second boost module 31, it can expand the function of the first power board 20 and increase the rated power generated by the power device 100. In this way, the power device 100 can be applicable to different direct-current inputs, thereby applying to different application situations of the user ends, which significantly improves the flexibility of the power device 100. Compared with the conventional development process, where a whole power device 100 is customized and developed according to different user ends, the power device 100 in this embodiment can save costs for design and development and improve development efficiency. In addition, the second power board 30 is arranged on the basis of the first power board 20, which facilitates the fabrication and installment of the power boards. By providing separable power boards, which is applicable to the fabrication and processing of the conventional circuit board, it can eliminate the limitation on improvement of the power of the power device 100 due to the limitation of the processing capacity.

In an embodiment, as shown in FIG. 1, the power device 100 further includes a conductive member 40. The conductive member 40 is connected between the first power board 20 and the second power board 30 to electrically connect the first power board 20 with the second power board 30.

In an embodiment, the conductive member 40 is a copper bar. The first power board 20 and the second power board 30 are spaced apart from each other. The first power board 20 is connected to the second power board 30 through the copper bar, so that the circuits of the first power board 20 and second power board 30 are conducted. In this way, the second power board 30 transmits the direct-current power boosted by the second boost module 31 to the first power board 20. The direct-current power is then boosted by the first boost module 21, the power boosted by the first boost module 21 is inverted by the inversion module 22 into the alternating-current power. As a result, the alternating-current power is outputted by the first power board 20. In another embodiment, the conductive member 40 may be other metal wires.

In another embodiment, a copper exposure region is formed on a side of the first power board 20, and another copper exposure region is formed on a side of the second power board 30, where the two sides are opposite to each other. The two copper exposure regions are in direct contact with each other, so that the circuits of the first power board 20 and second power board 30 are conducted.

In an embodiment, as shown in FIG. 1, at least two inversion modules 22 are arranged on the first power board 20. A distance from each of the at least two inversion modules 22 to the second boost module 31 is different from each other. The second boost module 31 is electrically connected to the inversion module 22 with the minimum distance to the second boost module 31.

The multiple inversion modules 22 arranged on the first power board 20 may be arranged in a matrix manner. As the second boost module 31 on the second power board 30 transmits the boosted direct-current power to the closest inversion module 22, it can prevent the direction in which the direct-current power is inputted to the second power board 30 from intersecting with the direction in which the direct-current power is inputted to the first power board 20, so that the direction in which the direct-current power is inputted to the second power board 30 is consistent with the direction in which the direct-current power is inputted to the first power board 20 (as shown by the dashed arrow lines in FIG. 1). In this way, it is beneficial to optimize the power device in the electromagnetic compatibility (EMC) design.

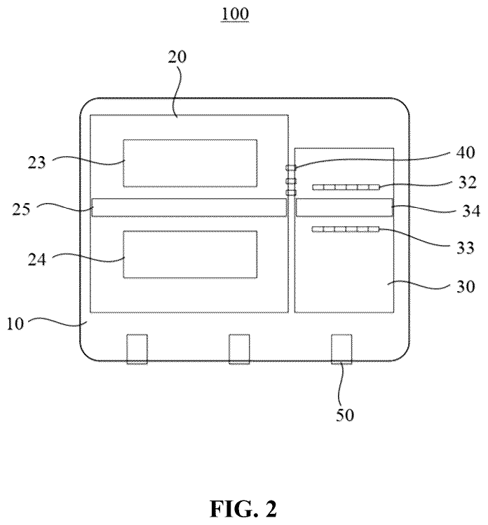

In an embodiment, as shown in FIG. 2, a first component 23 and a second component 24 are arranged on a surface of the first power board 20, and are spaced apart from each other. A first heat-dissipation air channel is formed between the first component 23 and the second component 24. A third component 32 and a fourth component 33 are arranged on a surface of the second power board 30, and are spaced apart from each other. A second heat-dissipation air channel is formed between the third component 32 and the fourth component 33. Where, the first heat-dissipation air channel is in communication with the second heat-dissipation air channel.

In an embodiment, the first boost module 21 and an inverter may be arranged on a back surface of the first power board 20, and the first component 23 and the second component 24 may be arranged on a front surface of the first power board 20. The first component 23 may be a direct-current input film capacitor, and the second component 24 may be a bus capacitor. A recess structure is formed between the first component 23 and the second component 24 on the first power board 20 due to the thickness of the first component 23 and the thickness of the second component 24. Such recess structure may be used for ventilation and heat-dissipation, thereby forming the first heat-dissipation air channel.

Similarly, the second boost module 31 and an inverter may be arranged on a back surface of the second power board 30, and the third component 32 and the fourth component 33 may be arranged on a front surface of the second power board 30. The third component 32 may be a direct-current input film capacitor, and the fourth component 33 may be a bus capacitor. A recess structure is formed between the third component 32 and the fourth component 33 on the second power board 30 due to the thickness of the third component 32 and the thickness of the fourth component 33. Such recess structure may be used for ventilation and heat-dissipation, thereby forming the second heat-dissipation air channel.

Since the first heat-dissipation air channel is in communication with the second heat-dissipation air channel, air entered from an air inlet of the housing 10 smoothly flows through the first heat-dissipation air channel and the second heat-dissipation air channel to an air outlet of the housing 10, and flows out of the housing 10 through the air outlet, thereby improving the effect of heat-dissipation on the first power board 20 and the second power board 30.

In an embodiment, as shown in FIG. 2, the first heat-dissipation air channel and the second heat-dissipation air channel are located on a same straight line.

In the embodiment, the first heat-dissipation air channel and the second heat-dissipation air channel are both linear air channels and arranged on the same line. By arranging the first heat-dissipation air channel and the second heat-dissipation air channel in a same direction, first heat-dissipation air channel can be in communication with the second heat-dissipation air channel through front to back, which facilitates air inside the housing 10 rapidly flowing, thereby improving the heat-dissipation capacity of the power device 100.

In an embodiment, the power device 100 further includes a first heat radiator. The first heat radiator includes a heat absorbing component arranged inside the housing 10. The first power board 20 is in contact with the heat absorbing component of the first heat radiator.

In an embodiment, the first heat radiator is a skiving heat radiator. Fins of the skiving heat radiator increases the contact area between the first heat radiator and air, so that heat generated by the first power board 20 during operation can be rapidly dissipated to effectively cool the first power board 20.

In an embodiment, the power device 100 further includes a second heat radiator. The second heat radiator includes a heat absorbing component arranged inside the housing 10. The second power board 30 is in contact with the heat absorbing component of the second heat radiator.

The second heat radiator may rapidly dissipate heat generated by the second power board 30 during operation, thereby effectively cooling the second power board 30. The second heat radiator may be a skiving heat radiator, a radiating tube, and the like. To meet the heat-dissipation requirements of the power device, the second power board 30 may be configured with a second heat radiator different from the type of first heat radiator (i.e., the second radiator and the first radiator are arranged independently), which can lower the costs.

In an embodiment, the power device 100 further includes a heat-dissipation fan. The heat-dissipation fan is arranged on the housing 10.

In an embodiment, the heat-dissipation fan is arranged on the housing 10, which can speed up the process of air flowing through the inside of the housing 10, thereby improving the heat-dissipation efficiency of the first power board 20 and the second power board 30.

In an embodiment, the power device 100 further includes a direct-current input board. The direct-current input board is arranged inside the housing 10. The direct-current input board is electrically connected to the first power board 20 and the second power board 30.

A photovoltaic panel absorbs solar energy and converts the solar energy into direct-current power, and the direct-current power is inputted to the direct-current input board. The direct-current input board is provided with a direct-current filter to filter the direct-current power, and inputs filtered direct-current power to the first power board 20 and the second power board 30. The direct-current power is boosted and inverted by the first power board 20 and the second power board 30 into alternating-current power, and the alternating-current power is outputted.

In an embodiment, as shown in FIGS. 1 to 2, the power device 100 further includes a direct-current input switch 50. The direct-current input switch 50 is arranged on the housing 10. The direct-current input board is electrically connected to the first power board 20 and the second power board 30 through the direct-current input switch 50.

The direct-current input switch 50 may be a knob structure. The direct-current input switch 50 is configured to control whether the direct-current input board transmits power to the first power board 20 and the second power board 30. In this way, the power generation process of the power device 100 can be controlled.

In an embodiment, the power device 100 further includes an alternating-current output board. The alternating-current output board is arranged inside the housing 10 and is electrically connected to the first power board 20.

The direct-current power is boosted and inverted by the first power board 20 and the second power board 30 into alternating-current power. The alternating-current power is transmitted to the alternating-current output board. The alternating-current output board is provided with an alternating-current filter to filter the alternating-current power, and outputs the filtered alternating-current power to the power grid.

A photovoltaic power generation device is further provided according to the present disclosure. The photovoltaic power generation device includes a photovoltaic assembly and a power device 100. For the detailed structures of the power device 100, reference is made to the foregoing embodiments. Given that the photovoltaic power generation device employs all technical solutions in the foregoing embodiments, it has at least all the beneficial effects of the technical solutions in the foregoing embodiments, which are not repeated herein. Where, the photovoltaic assembly is electrically connected to the first power board 20 and the second power board 30.

The preferred embodiments of the present disclosure are described above, and are not intended to limit the scope of the present disclosure. Any equivalent structural transformation made based on the specification and the drawings of the present disclosure or direct/indirect application in other related technical fields without departing from the concept of the present disclosure falls within the protection scope of the present disclosure.

1. A power device, comprising:
a housing;
a first power board, which is arranged inside the housing, wherein a first boost module and an inversion module are arranged on the first power board; and
a second power board, which is arranged inside the housing, wherein the second power board is electrically connected to the first power board, and a second boost module is arranged on the second power board.

2. The power device according to claim 1, further comprising a conductive member, wherein the conductive member is connected between the first power board and the second power board for the electric connection therebetween.

3. The power device according to claim 1, wherein at least two inversion modules are arranged on the first power board, a distance from each of the at least two inversion modules to the second boost module is different from each other, and the second boost module is electrically connected to the inversion module with a minimum distance to the second boost module.

4. The power device according to claim 1, wherein
a first component and a second component are arranged on a surface of the first power board and are spaced apart from each other, and a first heat-dissipation air channel is formed between the first component and the second component;
a third component and a fourth component are arranged on a surface of the second power board and are spaced apart from each other, and a second heat-dissipation air channel is formed between the third component and the fourth component; and
the first heat-dissipation air channel is in communication with the second heat-dissipation air channel.

5. The power device according to claim 4, wherein the first heat-dissipation air channel and the second heat-dissipation air channel are located on a same straight line.

6. The power device according to claim 1, further comprising:
a first heat radiator arranged inside the housing, and the first heat radiator is in contact with the first power board; and/or
the power device further comprises a second heat radiator arranged inside the housing, and the second heat radiator is in contact with the second power board.

7. The power device according to claim 1, further comprising:
a heat-dissipation fan arranged on the housing.

8. The power device according to claim 1, further comprising:
a direct-current input board, wherein
the direct-current input board is arranged inside the housing and is electrically connected to the first power board and the second power board.

9. The power device according to claim 8, further comprising:
a direct-current input switch, wherein
the direct-current input switch is arranged on the housing, and the direct-current input board is electrically connected to the first power board and the second power board through the direct-current input switch.

10. The power device according to claim 1, further comprising:
an alternating-current output board, wherein
the alternating-current output board is arranged inside the housing and is electrically connected to the first power board.

11. A photovoltaic power generation device, comprising:
a photovoltaic assembly; and
a power device
wherein the power device comprises:
a housing;
a first power board, which is arranged inside the housing, wherein a first boost module and an inversion module are arranged on the first power board; and
a second power board, which is arranged inside the housing, wherein the second power board is electrically connected to the first power board, and a second boost module is arranged on the second power board;
wherein the photovoltaic assembly is electrically connected to the first power board and the second power board.

12. The photovoltaic power generation device according to claim 11, the power device further comprises: a conductive member, wherein the conductive member is connected between the first power board and the second power board for the electric connection therebetween.

13. The photovoltaic power generation device according to claim 11, wherein at least two inversion modules are arranged on the first power board, a distance from each of the at least two inversion modules to the second boost module is different from each other, and the second boost module is electrically connected to the inversion module with a minimum distance to the second boost module.

14. The photovoltaic power generation device according to claim 11, wherein
a first component and a second component are arranged on a surface of the first power board and are spaced apart from each other, and a first heat-dissipation air channel is formed between the first component and the second component;
a third component and a fourth component are arranged on a surface of the second power board and are spaced apart from each other, and a second heat-dissipation air channel is formed between the third component and the fourth component; and
the first heat-dissipation air channel is in communication with the second heat-dissipation air channel.

15. The photovoltaic power generation device according to claim 14, wherein the first heat-dissipation air channel and the second heat-dissipation air channel are located on a same straight line.

16. The photovoltaic power generation device according to claim 11, the power device further comprises:
a first heat radiator arranged inside the housing, and the first heat radiator is in contact with the first power board; and/or
the power device further comprises a second heat radiator arranged inside the housing, and the second heat radiator is in contact with the second power board.

17. The photovoltaic power generation device according to claim 11, the power device further comprises: a heat-dissipation fan arranged on the housing.

18. The photovoltaic power generation device according to claim 11, the power device further comprises: a direct-current input board, wherein
the direct-current input board is arranged inside the housing and is electrically connected to the first power board and the second power board.

19. The photovoltaic power generation device according to claim 18, the power device further comprises: a direct-current input switch, wherein
the direct-current input switch is arranged on the housing, and the direct-current input board is electrically connected to the first power board and the second power board through the direct-current input switch.

20. The photovoltaic power generation device according to claim 11, the power device further comprises: an alternating-current output board, wherein the alternating-current output board is arranged inside the housing and is electrically connected to the first power board.
